(19) United States
(12) Patent Application Publication
(10) Pub. No.: US 2015/0340400 A1
(43) Pub. Date: Nov. 26, 2015

(54) STACKED SOLID-STATE IMAGING DEVICE AND IMAGING APPARATUS

(71) Applicant: OLYMPUS CORPORATION, Tokyo (JP)

(72) Inventors: Yoshiaki Takemoto, Tokyo (JP); Mitsuhiro Tsukimura, Tokyo (JP); Naohiro Takazawa, Tokyo (JP)

(73) Assignee: OLYMPUS CORPORATION, Tokyo (JP)

(21) Appl. No.: 14/817,539

(22) Filed: Aug. 4, 2015

Related U.S. Application Data
(63) Continuation of application No. PCT/JP2014/051349, filed on Jan. 23, 2014.

(30) Foreign Application Priority Data
Feb. 6, 2013 (JP) 2013-021712

(51) Int. Cl. H01L 27/146

(52) U.S. Cl. CPC H01L 27/14636; H01L 27/14634; H01L 27/14632

(57) ABSTRACT

A stacked solid-state imaging device includes a first substrate and a second substrate that are stacked on each other, a photoelectric conversion unit that converts incident light into an electrical signal, an electrode portion that is provided on the first substrate and has an exposed surface exposed to the outside in order to deliver an electrical signal to and from the outside, a connection portion that electrically connects a first contact portion provided on the first substrate and a second contact portion provided on the second substrate, and a wiring portion that is provided on the first substrate and electrically connects the electrode portion and the first contact portion in which the connection portion is arranged so as not to overlap the exposed surface when seen from a stacked direction in which the first substrate and the second substrate are stacked on each other.

### BACKGROUND OF THE INVENTION

1. Field of the Invention

The present invention relates to a stacked solid-state imaging device, and more particularly, to a stacked solid-state imaging device which is configured to receive light from the back side thereof, and an imaging apparatus including the stacked solid-state imaging device.

This application is a continuation application based on PCT/JP2014/051349, filed on Jan. 23, 2014 and claiming priority based on Japanese Patent Application No. 2013-021712, filed in Japan on Feb. 6, 2013. The contents of both the Japanese Patent Application and the PCT Application are incorporated herein by reference.

2. Description of Related Art

In recent years, video cameras, electronic still cameras, and the like have become widespread in the general public. A charge coupled device (CCD) type or an amplification type solid-state imaging device is used for the cameras. In the amplification type solid-state imaging device, signal charges generated and accumulated by a photoelectric conversion unit of a pixel on which light is incident are guided to an amplification unit provided in the pixel, and a signal amplified by the amplification unit is output from the pixel. In the amplification type solid-state imaging device, a plurality of pixels are arranged in a two-dimensional matrix. Examples of the amplification type solid-state imaging device include a complementary metal oxide semiconductor (CMOS) type solid-state imaging device using a CMOS transistor, and the like.

Hitherto, a general CMOS type solid-state imaging device has adopted a method of sequentially reading out signal charges, which are generated by photoelectric conversion units of pixels arrayed in a two-dimensional matrix, for each row. In this method, an exposure timing in the photoelectric conversion unit of each pixel is determined by the start and termination of the read-out of signal charge, and thus the exposure timing is different for each row. For this reason, when a fast-moving subject is captured using such a CMOS type solid-state imaging device, the subject may be distorted in the captured image.

In order to remove the distortion of the subject, a simultaneous imaging function (global shutter function) for realizing the simultaneity of accumulation of signal charges has been proposed. In addition, uses of a CMOS type solid-state imaging device having a global shutter function have diversified. The CMOS type solid-state imaging device having a global shutter function is generally required to include a storage capacity unit having a light shielding property, in order to store signal charges generated by photoelectric conversion units until read-out is performed.

In such a CMOS type solid-state imaging device of the related art, after all pixels are simultaneously exposed, signal charges generated by the respective photoelectric conversion units are simultaneously transmitted to the respective storage capacity units in all pixels and are temporarily accumulated, and the signal charges are sequentially converted into pixel signals at a predetermined read-out timing and are read out.

In the CMOS type solid-state imaging device having a global shutter function of the related art, it is necessary to form the photoelectric conversion units and the storage capacity units on the same plane of the same substrate, and thus a chip area inevitably increases. Further, there is a problem in that the quality of a signal may deteriorate due to noise caused by light and noise caused by a leakage current (dark current) generated in the storage capacity unit during a standby period until the signal charges accumulated in the storage capacity units are read out.

In order to solve the above-mentioned problem, a stacked solid-state imaging device disclosed in Japanese Unexamined Patent Application, First Publication No. 2012-33878 has been examined.

In the stacked solid-state imaging device, a first substrate and a second substrate are electrically connected to each other by a connection layer (connection portion) including a micro-pad and a micro-bump. Pixel arrays having pixels arrayed in a two-dimensional matrix are arrayed on the first substrate, and a bonding pad (electrode portion) in which an electrode configured to input a signal to and output a signal from the outside is exposed is formed on the same plane.

The bonding pad is arranged in a pad portion, and is exposed to the outside through an opening formed in the pad portion.

### SUMMARY OF THE INVENTION

According to first aspect of the invention, there is provided an stacked solid-state imaging device including a first substrate and a second substrate that are stacked on each other, a photoelectric conversion unit that converts incident light into an electrical signal, an electrode portion that is provided on the first substrate and has an exposed surface exposed to an outside in order to deliver an electrical signal to and from the outside, a connection portion that electrically connects a first contact portion provided on the first substrate and a second contact portion provided on the second substrate, and a wiring portion that is provided on the first substrate and electrically connects the electrode portion and the first contact portion, in which the connection portion is arranged so as not to overlap the exposed surface when seen from a stacked direction in which the first substrate and the second substrate are stacked on each other, and in which the wiring portion includes a parallel wiring portion that is formed in parallel with the first substrate and is electrically connected to the electrode portion, a first crossing wiring portion that is formed to cross the first substrate and is electrically connected to the parallel wiring portion, and a second crossing wiring portion that is formed to cross the first substrate and is electrically connected to the first crossing wiring portion and the first contact portion.

According to a second aspect of the invention, in the first aspect, the wiring portion may be arranged so as not to overlap the exposed surface when seen from the stacked direction.

According to a third aspect of the invention, in the first aspect, an entire electrode portion may be formed on a reference surface parallel to the first substrate.

An imaging apparatus according to a fourth aspect of the invention includes the stacked solid-state imaging device according to any one of the first to third aspects.

### BRIEF DESCRIPTION OF THE DRAWINGS

FIG. 1 is a perspective view of a stacked solid-state imaging device according to a first embodiment of the invention.

FIG. 2 is a cross-sectional view of a side surface of a main portion of the stacked solid-state imaging device according to the first embodiment of the invention.

FIG. 3 is a cross-sectional view of a main portion according to a modification example of the first embodiment of the invention.

FIG. 4 is a cross-sectional view of a main portion of a stacked solid-state imaging device according to a second embodiment of the invention.

FIG. 5 is a block diagram of an imaging apparatus according to a third embodiment of the invention.

### DETAILED DESCRIPTION OF THE INVENTION

### First Embodiment

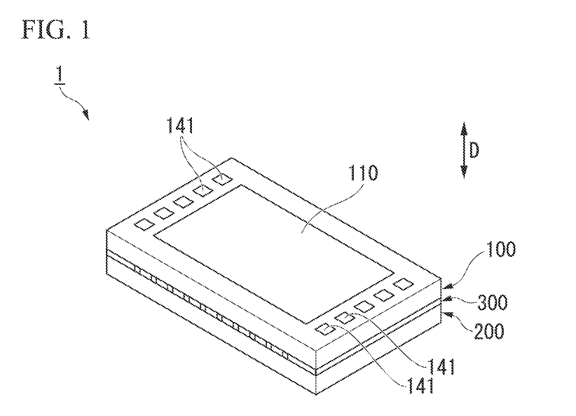

Hereinafter, a stacked solid-state imaging device according to a first embodiment of the invention will be described with reference to FIGS. 1 to 3.

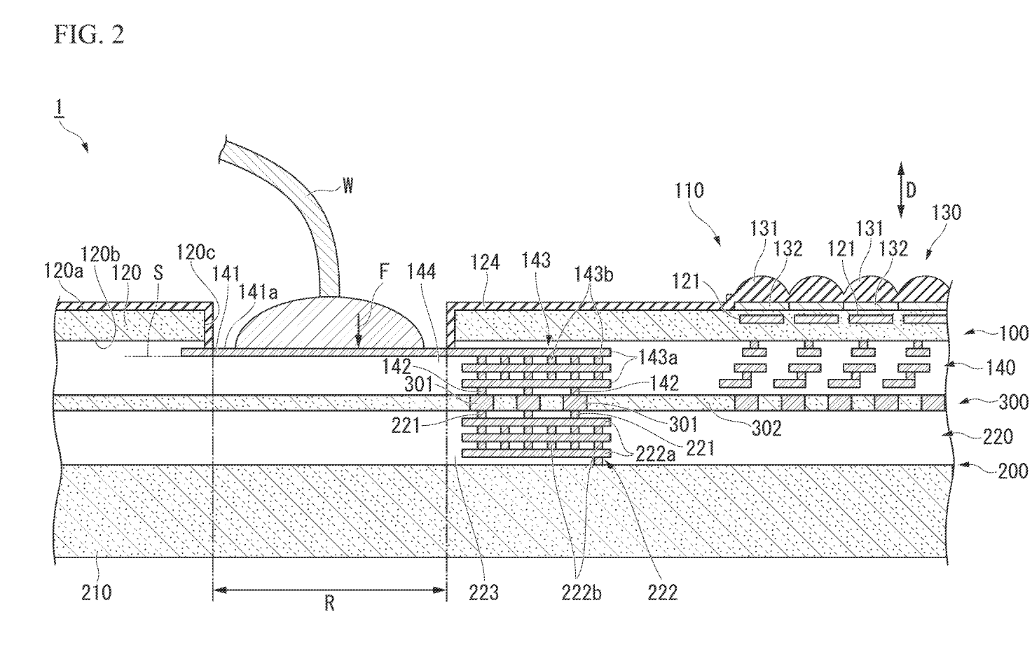

As shown in FIGS. 1 and 2, a stacked solid-state imaging device 1 includes a photoelectric conversion unit 110 for converting incident light into an electrical signal, a first substrate 100 including a read-out circuit, not shown in the drawing, which reads out the converted electrical signal, a second substrate 200 including a driving circuit not shown in the drawing, and a connection layer 300 that connects the first substrate 100 and the second substrate 200.

The first substrate 100 and the second substrate 200 are stacked in a stacked direction D.

As shown in FIG. 2, the first substrate 100 includes a base material 120 formed of silicon or the like in a plate shape, a light incident portion 130 provided on a first surface 120a of the base material 120, and a first wiring structure 140 provided on a second surface 120b of the base material 120.

The base material 120 is provided with a through hole 120c penetrating the base material in the stacked direction D. A plurality of photodiode portions 121 including a photodiode and the above-mentioned read-out circuit are built into the base material 120 along the first surface 120a.

The plurality of photodiode portions 121 constitute a pixel array. The light incident portion 130 and the photodiode portions 121 constitute the photoelectric conversion unit 110.

The light incident portion 130 includes a plurality of microlenses 131 and a plurality of color filters 132. The microlenses 131 are arranged corresponding to the photodiode portions 121, and guide light incident on the light incident portion 130 to the photodiode portions 121.

The color filter 132, which is a known filter, is configured such that a filter of one color selected from a plurality of kinds of colors is allocated to each of photodiode portions 121.

A known protection film 124 is provided on a portion of the first surface 120a of the base material 120, which is not provided with the light incident portion 130, and on the inner surface of the through hole 120c.

The first wiring structure 140 is constituted by an interlayer insulating film, a wiring layer, a via, and the like which are formed through a known semiconductor process. The first wiring structure 140 includes a bonding pad (electrode portion) 141, first bumps (first contact portions) 142, and a wiring portion 143.

The bonding pad 141 is formed on the base material 120 side in the first wiring structure 140 so as to be parallel to the second surface 120b. In other words, the entire bonding pad 141 is formed on a reference surface S parallel to the second surface 120b of the base material 120.

A portion of a surface of the bonding pad 141 on the base material 120 side is an exposed surface 141a which is exposed to the outside without being covered with the base material 120 and the protection film 124. The exposed surface 141a is formed to be perpendicular to the stacked direction D. In this example, since an interlayer insulating film 144 to be described later and the protection film 124 cover a portion of one surface of the bonding pad 141, the remaining portion of one surface of the bonding pad 141 is an exposed surface 141a.

The bonding pad 141 is a pad configured to deliver an electrical signal to and from the outside, that is, configured to input and output an electrical signal.

The first bumps 142 are formed on a surface opposite to the base material 120 in the first wiring structure 140.

The wiring portion 143 is configured as a multi-layer wiring in which the plurality of wirings (parallel wiring portions) 143a are arranged in a multi-layer manner with the interlayer insulating film 144 interposed therebetween and the wirings 143a are electrically connected to each other through vias (crossing wiring portions) 143b. The wirings 143a are formed in parallel with the second surface 120b of the base material 120, and the vias 143b are formed to be perpendicular to the second surface 120b.

The wiring 143a closest to the base material 120 side in the plurality of wirings 143a is formed integrally with the bonding pad 141. The wiring portion 143 electrically connects the bonding pad 141 and the first bumps 142.

The wiring portion 143 is arranged outside a region R overlapping the exposed surface 141a of the bonding pad 141 when seen in the stacked direction D.

The first substrate 100 configured in this manner is bonded to the second substrate 200 so that light is incident on the base material 120, that is, a silicon layer.

The first substrate 100 has the same configuration as a so-called rear surface irradiation type solid-state imaging device.

As shown in FIG. 2, the second substrate 200 includes a base material 210 formed of silicon or the like in a plate shape and a second wiring structure 220 provided on the base material 210.

A semiconductor element not shown in the drawing is provided on at least one surface of the base material 210.

The second wiring structure 220 can be configured in the same manner as the first wiring structure 140 mentioned above. The second wiring structure 220 includes second bumps (second contact portions) 221 and a second wiring portion 222.

The second bumps 221 are formed on a surface opposite to the base material 210 in the second wiring structure 220.

The second wiring portion 222 is configured as a multi-layer wiring in which a plurality of wirings 222a are arranged in a multi-layer manner with an interlayer insulating film 223 interposed therebetween and the wirings 222a are electrically connected to each other through vias 222b.

The above-mentioned driving circuit included in the second substrate 200 is an electric circuit not shown in the drawing within the first substrate 100 and the second substrate 200, and is a circuit configured to drive the photodiode portion 121 and the like.

The connection layer 300 includes a plurality of connection portions 301 each of which electrically connects the first bumps 142 of the first substrate 100 and the second bumps 221 of the second substrate 200, and a filling member 302 which is filled between the connection portions 301 adjacent to each other.

The connection portion 301 can be formed of solder, a metal, or the like. An insulating resin can be preferably used as the filling member 302. In the present embodiment, the connection portion 301 bonds the bumps 142 and 221 together using solder.

The connection portions 301 are arranged outside the region R overlapping the exposed surface 141a of the bonding pad 141 when seen in the stacked direction D.

The connection of a metal wire W to the bonding pad 141 of the stacked solid-state imaging device 1 configured in this manner is performed, for example, by the following procedures.

That is, the metal wire W is sent out forward from a cylinder hole of a head, not shown in the drawing, which is formed in a cylindrical shape.

The head includes an ultrasonic device.

A tip portion of the metal wire W is pressed against the exposed surface 141a of the bonding pad 141 while being melted by ultrasonic vibration generated by the ultrasonic device, and thus a load indicated by an arrow F perpendicular to the exposed surface 141a is applied to the exposed surface 141a.

In general, the first substrate 100 and the second substrate 200 are formed through a known semiconductor process, and thus are harder than the connection layer 300. The load from the metal wire W is mainly applied to the region R.

When a melted portion of the metal wire W cools down and solidifies, the metal wire W is connected to the exposed surface 141a.

Next, the operation of the stacked solid-state imaging device 1 configured in the above-identified manner will be described.

Light incident on the light incident portion 130 passes through the microlenses 131 and the color filters 132 and is then incident on the photodiode portions 121. The light incident on the photodiode portions 121 is photoelectrically converted into an electrical signal. The electrical signal is output to the metal wire W through the wirings 143a and the vias 143b of the first wiring structure 140 and the exposed surface 141a of the bonding pad 141.

The electrical signal input to the exposed surface 141a of the bonding pad 141 through the metal wire W is input to the semiconductor element of the second substrate 200 through the wiring portion 143 and the connection portions 301. In contrast, the signal output from the semiconductor element is output to the metal wire W through the exposed surface 141a.

As described above, according to the stacked solid-state imaging device 1 of the present embodiment, the connection portions 301 are arranged in the region R that does not overlap the exposed surface 141a of the bonding pad 141 when seen in the stacked direction D. When the metal wire W is connected to the exposed surface 141a, a load from the metal wire W is mainly applied to the region R, and thus it is possible to reduce the load applied to the connection portions 301 arranged outside the region R. Therefore, it is possible to suppress the occurrence of cracking and peeling in the vicinity of the connection portions 301 at the time of performing wire bonding on the exposed surface 141a. As a result, it is possible to increase the reliability of the stacked solid-state imaging device 1.

The wiring portion 143 is arranged outside the region R that overlaps the exposed surface 141a of the bonding pad 141 when seen in the stacked direction D. Thereby, it is possible to reduce the load applied to the vicinity of the wiring portion 143 at the time of performing wire bonding on the exposed surface 141a and to suppress the occurrence of cracking and peeling in the wiring portion 143.

The entire bonding pad 141 is formed on the reference surface S. Therefore, it is possible to form the entire bonding pad 141 at one time through a semiconductor process such as photolithography.

Since the wiring portion 143 includes the wirings 143a and the vias 143b, the wiring portion 143 is three-dimensionally configured as a multi-layer wiring, and thus it is possible to increase the degree of freedom in configuring the wiring portion 143.

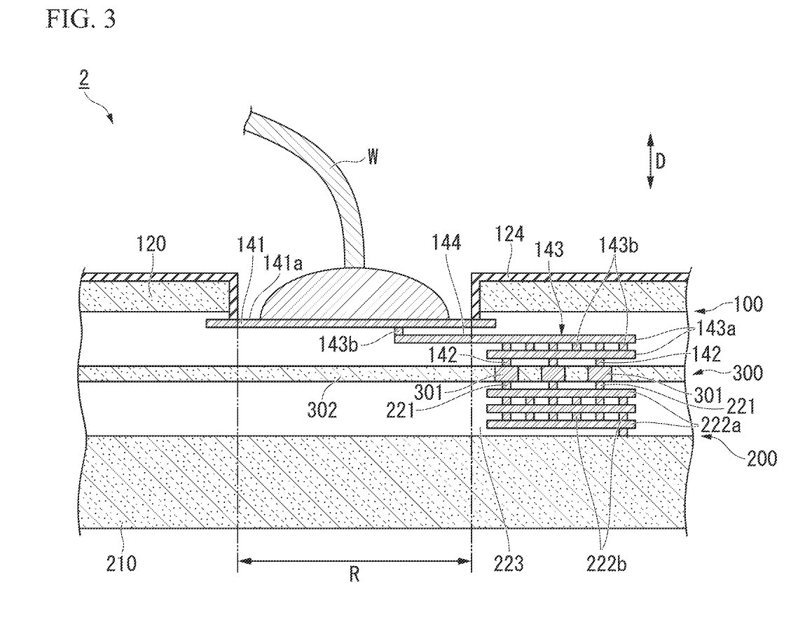

Meanwhile, in the present embodiment, as in a stacked solid-state imaging device 2 shown in FIG. 3, a configuration may be adopted in which some of the wirings 143a of the wiring portion 143 and the vias 143b are arranged in the region R that overlaps the exposed surface 141a of the bonding pad 141, when seen in the stacked direction D.

This is because the first substrate 100 is harder than the connection layer 300 as described above, which is less likely to cause cracking and peeling in the vicinity of the wirings 143a and the vias 143b arranged in the region R in such a configuration.

### Second Embodiment

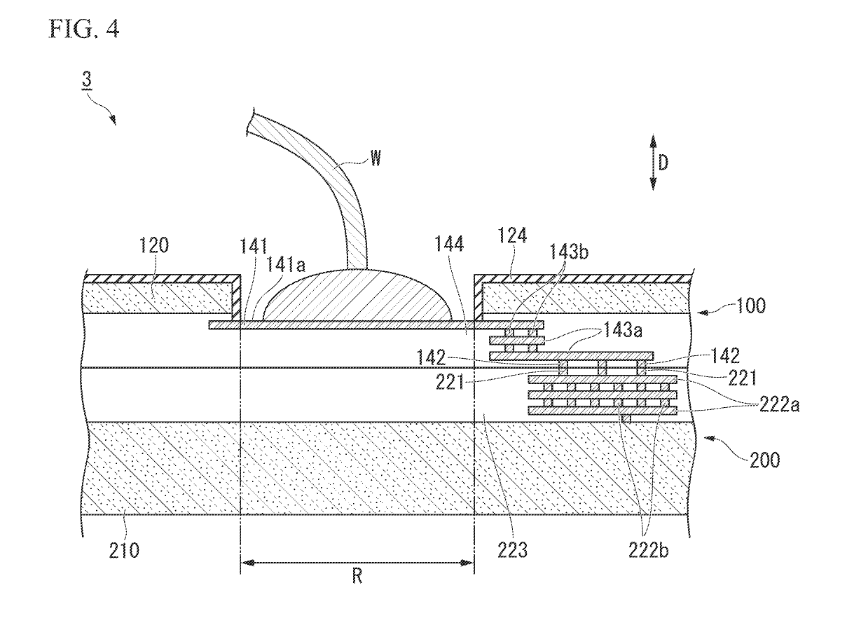

Next, a second embodiment of the invention will be described with reference to FIG. 4. The same portions as those in the previous embodiment are denoted by the same reference numerals and signs. Thus, a description thereof will be omitted here, and only differences will be described.

As shown in FIG. 4, a stacked solid-state imaging device 3 of the present embodiment is configured such that the connection layer 300 is omitted in the stacked solid-state imaging device 1 of the first embodiment.

In this example, first bumps 142 of a first substrate 100 and second bumps 221 of a second substrate 200 are directly bonded to each other.

That is, for example, preprocessing is performed on the bumps 142 and 221 to expose the bonding surfaces of the bumps 142 and 221. The exposed bonding surfaces are formed of the same material as base materials of the bumps 142 and 221. For example, the bumps 142 and 221 are directly bonded to each other under a vacuum environment, using means such as surface activation bonding in which the bonding surfaces are pressed against each other.

Also in the stacked solid-state imaging device 3 configured in this manner, it is possible to suppress the occurrence of cracking and peeling in the vicinity of a connection portion when wire bonding is performed. As a result, it is possible to provide the stacked solid-state imaging device 3 with high reliability.

Although the first and second embodiments of the invention have been described so far with reference to the accompanying drawings, the detailed configurations thereof are not limited thereto, and modifications and combinations of the configurations can be made without departing from the scope of the invention. Further, it is needless to say that the configurations described in the embodiments can be appropriately combined with each other and used.

For example, in the first and second embodiments, a stacked solid-state imaging device is configured by stacking two substrates 100 and 200. However, the number of substrates constituting the stacked solid-state imaging device is not limited thereto, and a stacked solid-state imaging device may be configured by stacking three or more substrates.

In this case, it is preferable that lamination is performed by appropriately forming a through silicon via (TSV) in a substrate.

Although it is assumed that the driving circuit is included in the second substrate 200, a configuration may also be adopted in which both the first substrate 100 and the second substrate 200 includes a driving circuit.

A bonding pad 141 may be configured as a multi-layer wiring including wirings and vias which are parallel to a base material 120. With such a configuration, it is possible to three-dimensionally configure a bonding pad and to increase the degree of freedom in configuring the bonding pad.

A wiring portion 143 may be constituted by only one wiring 143a.

A method of bonding the first substrate 100 and the second substrate 200 may be a method other than bump bonding and direct bonding.

### Third Embodiment

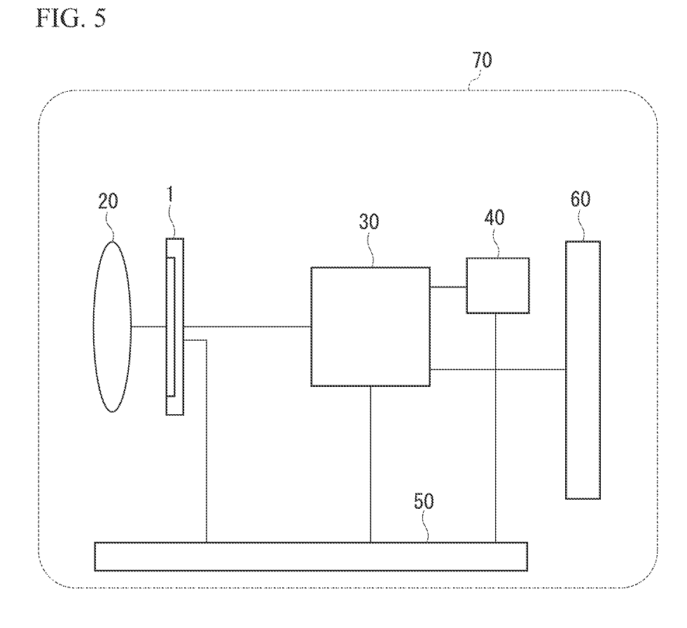

Next, an imaging apparatus of the invention equipped with the stacked solid-state imaging device 1, 2, or 3 according to the first or second embodiment will be described. FIG. 5 is a block diagram showing a schematic configuration of an imaging apparatus (for example, a digital monocular camera, an endoscope, or a microscope) 70 having the stacked solid-state imaging device 1 according to the embodiment of the invention mounted therein.

Hereinafter, an example of the imaging apparatus 70 having the stacked solid-state imaging device 1 according to the first embodiment mounted therein will be described.

The imaging apparatus 70 includes a lens unit 20, the stacked solid-state imaging device 1, an image signal processing device 30, a recording device 40, a camera control device 50, and a display device 60.

The lens unit 20 is configured such that the zooming, focusing, and stopping-down thereof are driven and controlled by the camera control device 50, and forms an image of a subject on the stacked solid-state imaging device 1.

The stacked solid-state imaging device 1 is driven and controlled by the camera control device 50, converts light from a subject which is incident on the stacked solid-state imaging device 1 through the lens unit 20 into an electrical signal, and outputs an image signal based on the amount of incident light to the image signal processing device 30.

The image signal processing device 30 performs processing such as the amplification of a signal, conversion into image data, various corrections, and the compression of image data on the image signal output from the stacked solid-state imaging device 1.

The image signal processing device 30 uses a memory, not shown in the drawing, as temporary storage means for image data in each processing.

The recording device 40, which is a detachable recording medium such as a semiconductor memory, records and reads out image data.

The camera control device 50 is a control device that controls the entire imaging apparatus 70.

The display device 60 is a display device such as a liquid crystal display device which displays an image formed on the stacked solid-state imaging device 1 and based on image data processed by the image signal processing device 30 or image data read out from the recording device 40.

As described above, the stacked solid-state imaging device 1 of the first embodiment is mounted in the imaging apparatus 70 of the present embodiment. Thereby, it is possible to suppress the occurrence of cracking and peeling in the vicinity of a connection portion 301 when wire bonding is performed on the stacked solid-state imaging device 1. As a result, it is possible to provide the imaging apparatus 70 with high reliability.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A stacked solid-state imaging device comprising:
a first substrate and a second substrate which are stacked on each other;
a photoelectric conversion unit which converts incident light into an electrical signal;
an electrode portion which is provided on the first substrate and has an exposed surface exposed to an outside in order to deliver an electrical signal to and from the outside;
a connection portion which electrically connects a first contact portion provided on the first substrate and a second contact portion provided on the second substrate; and
a wiring portion which is provided on the first substrate and electrically connects the electrode portion and the first contact portion,
wherein the connection portion is arranged so as not to overlap the exposed surface when seen from a stacked direction in which the first substrate and the second substrate are stacked on each other, and
wherein the wiring portion includes
a parallel wiring portion that is formed in parallel with the first substrate and is electrically connected to the electrode portion,
a first crossing wiring portion that is formed to cross the first substrate and is electrically connected to the parallel wiring portion, and
a second crossing wiring portion that is formed to cross the first substrate and is electrically connected to the first crossing wiring portion and the first contact portion.

2. The stacked solid-state imaging device according to claim 1, wherein the wiring portion is arranged so as not to overlap the exposed surface when seen from the stacked direction.

3. The stacked solid-state imaging device according to claim 1, wherein an entire electrode portion is formed on a reference surface parallel to the first substrate.

4. An imaging apparatus comprising the stacked solid-state imaging device according to claim 1.

5. An imaging apparatus comprising the stacked solid-state imaging device according to claim 2.

6. An imaging apparatus comprising the stacked solid-state imaging device according to claim 3.
